(19) United States
(12) Patent Application Publication
(10) Pub. No.: US 2009/0072304 A1
(43) Pub. Date: Mar. 19, 2009

(54) Trench misfet

(76) Inventor: Alberto O. Adan, Nara (JP)

Correspondence Address: HARNESS, DICKEY & PIERCE, P.L.C., P.O. BOX 8910, RESTON, VA, 20195, US

(21) Appl. No.: 11/918,743

(22) PCT Filed: Aug. 2, 2006
(86) PCT No.: PCT/JP2006/315267

§ 371 Date: Oct. 18, 2007

(30) Foreign Application Priority Data
Aug. 3, 2005 (JP) 2005-225849

(51) Int. Cl. H01L 29/78

(52) U.S. Cl. 257/330; 257/E29.264

(57) ABSTRACT

In one embodiment of the present invention, trench sections cause regions where source diffusion sections and body diffusion sections are formed to be partitioned into line regions. The trench sections are formed not in a straight line shape but in a zigzag shape. Two adjacent trench sections are provided to be axisymmetric, having an axis of symmetry in a longitudinal direction of the trench sections. A wide region and a narrow region are alternately formed in each of the regions, partitioned by the trench sections, in which regions the source diffusion sections and the body diffusion sections are formed. Each of the body diffusion sections is formed in the wide region. This makes it possible to realize an improved power MOSFET that achieves a reduction in an ON resistance per unit cell and an increase in a layout effect.

### TECHNICAL FIELD

The present invention relates in general to the structure of a semiconductor device and in particular to a trench MISFET (Metal-Insulator-Semiconductor Field Effect Transistor), the trench MISFET having useful applications in power supply devices, for example, DC-DC converters and high-side load drives.

### BACKGROUND ART

Vertical trench MOSFETs (Metal-Oxide-Semiconductor Field Effect Transistors) have been conventionally used widely in power supply control electronic apparatuses due to their advantages such as their efficient structure and low ON resistance.

FIG. 5 is a cross sectional view illustrating a structure of a conventional, typical n-channel trench MOSFET. (See, for example, Non-Patent Document 1). The n-channel trench MOSFET includes a substrate 101, an epitaxial layer 102, a body section 103, source diffusion sections 104, and body diffusion sections (a pattern of the body diffusion sections (not illustrated in FIG. 5) is formed in the same layer as a pattern of the source diffusion sections) which are laminated in this order. Moreover, each trench section 105 is formed so as to penetrate the source diffusion section 104 and the body section 103 and reach the epitaxial layer 102. A gate electrode section 106 is embedded in the trench section 105. The gate electrode section 106 is insulated from the source diffusion section 104 by a gate insulator 107.

Here, the trench MOSFET has two key parameters: (a) breakdown voltage (hereinafter, referred to as “BVdss” where appropriate) and (b) ON resistance (hereinafter, referred to as “Ron” where appropriate).

FIG. 6 illustrates physical locations of components of a MOSFET along with individual component resistances of the ON resistance. In FIG. 6, Rs is the diffusion and contact resistance of the source section, Rch the resistance of the induced channel section of the MOSFET (induced MOSFET), Racc the resistance of the overlap (accumulation) of the gate and the drain, Rdrift the resistance of the lightly doped drain section, and Rsub the resistance of the heavily doped drain section (substrate).

The MOSFET's ON resistance Ron is related to the resistances of the components as illustrated in FIG. 6 by the following equation (1):

Ron=Rs+Rch+Racc+Rdrift+Rsub (1)

To achieve a large breakdown voltage (BVdss), the concentration of impurity introduced to the drift section generally needs to be low. However, if the concentration is lowered, the Rdrift is increased, which in turn increases the ON resistance Ron of the MOSFET as a whole. So, there is a tradeoff between Ron and BVdss.

For performing a correct device operation, the MOSFET needs to be provided with a contact for each transistor body section (hereinafter, referred to as a body contact). Generally, the body section of a trench MOSFET is electrically connected with (contacts) the source section.

This body contact is necessary to reduce a parasitic resistance (Rb) of a body section in a parasitic bipolar transistor formed among a source (emitter), a body (base), and a drain (collector) and to prevent the parasitic bipolar transistor from being turned on. During a MOSFET operation at a high voltage application between the source and the drain, an impact ionization created by many carriers may flow through a body resistance (Rb) if the parasitic transistor is turned on. This reduces a maximum operating voltage.

However, because the formation of the body contact consumes an area in a cell and increases an area of each cell, the formation of the body contact deteriorates efficiency of the MOSFET.

In a conventional arrangement, the power MOSFET is designed with an array of equal cells. Examples of such cells are hexagon cells as illustrated in FIG. 7(a) and square cells as illustrated in FIG. 7(b). A body contact is provided to a center of each cell. As illustrated in FIG. 7(c), Patent Document 1 discloses, as another example of the conventional arrangement, a striped arrangement in which a stripe in the center of the cell is arranged to serve as a body contact.

Other than the conventional art disclosed in the document mentioned above, Patent Documents 2 through 5 disclose conventional art concerning a trench MOSFET.

[Patent Document 1] U.S. Pat. No. 5,168,331

[Patent Document 2] Japanese Unexamined Patent Publication No. 213951/1997 (Tokukaihei 9-213951) (published on Aug. 15, 1997)

[Patent Document 3] Japanese Unexamined Patent Publication No. 23092/1996 (Tokukaihei 8-23092) (published on Jan. 23, 1996)

[Patent Document 4] Japanese Unexamined Patent Publication No. 354794/1999 (Tokukaihei 11-354794) (published on Dec. 24, 1999)

[Patent Document 5] Japanese Unexamined Patent Publication No. 324197/2003 (Tokukai 2003-324197) (published on Nov. 14, 2003)

[Non-Patent Document 1] Krishna Shenai, “Optimized Trench MOSFET Technologies for Power Devices”, IEEE Transactions on Electron Devices, Vol. 39, No. 6, p. 1435-1443, June, 1992

### DISCLOSURE OF INVENTION

However, these trench MOSFET techniques of conventional art have following issues (A) and (B).

(A) A body contact electrically connected to a source requires a large area.
(B) Conventional cell shapes (hexagon and square shaped types) have a limitation in providing the cells at a fine pitch because the cell shapes require relatively large areas for a body diffusion section (body contact).

An object of the present invention is to realize an improved power MOSFET that reduces an ON resistance per unit cell and enhances a layout effect.

In order to solve the object mentioned above, a trench MISFET of the present invention includes trench sections, on a semiconductor substrate, in which a gate electrode is embedded, the substrate including: a heavily doped drain section of a first conductive type; a lightly doped drain section of the first conductive type; a channel body section of a second conductive type; and a source section of the first conductive type, the sections being formed in this order adjacently, source diffusion sections and body diffusion sections being formed in the source section, the trench sections causing regions where the source diffusion sections and the body diffusion sections are formed to be partitioned by alternately forming a wide region and a narrow region in each of the regions where the source diffusion sections and the body diffusion sections are formed, and each of the body diffusion sections being provided in wide regions in each of the regions partitioned by the trench sections.

The arrangement includes body contacts (contact sections each being between the source and the body) for providing electric potential to the channel body section by formation of the source diffusion sections and the body diffusion sections in the source section. The formation of such body contacts, namely, provision of the body diffusion sections is necessary for causing a MISFET to perform a correct device operation. However, the formation of each of the body contacts consumed a large area in a cell area and lead to an increase in the cell area. This deteriorated the efficiency of the MISFET.

On the other hand, according to the arrangement mentioned above, a wide region and a narrow region are alternately formed in the regions, including the source diffusion sections and the body diffusion sections, which regions are partitioned by the trench sections. Each of the body diffusion sections is provided in the wide region. This makes it possible, as a whole, to prevent each width between the trench sections from increasing while the body diffusion sections (body contacts) are kept in the arrangement. In other words, the area per unit cell can be suppressed.

Moreover, for alternate formation of the wide region and the narrow region in the regions including the source diffusion sections and the body diffusion sections, the trench sections are formed to have, for example, a zigzag-shaped part. This increases the length of the periphery of each of the trench sections in a plane, compared with a case where each of the trench sections is formed in a straight line. This leads to an increase in the channel width of the MOSFET.

Namely, in the trench MOSFET, the pattern layout of the trench sections, the source diffusion sections, and the body diffusion sections as mentioned above leads to an effect such that a cell area is reduced and a channel width is increased. Accordingly, the efficiency of the trench MOSFET can be increased (ON resistance can be reduced).

### BRIEF DESCRIPTION OF DRAWINGS

FIG. 1 is a plane view illustrating one example of a layout pattern of a trench section, a source diffusion section, and a body diffusion section in a trench MOSFET according to an embodiment of the present invention.

FIG. 2 is a cross sectional view taken along X-X of FIG. 1, illustrating an arrangement of a substantial part of the trench MOSFET.

FIG. 3 is a plane view illustrating an example of a layout pattern of a trench section, a source diffusion section, and a body diffusion section in a trench MOSFET according to the embodiment of the present invention, the pattern being different from the pattern as illustrated in FIG. 1.

FIG. 4(a) is a graph illustrating a result of comparison of a layout effect of a conventional square cell pattern and layout effects of a meander cell pattern and a keyhole cell pattern of the present invention.

FIG. 4(b) is a graph illustrating an efficiency ratio of an efficiency of the meander cell pattern to an efficiency of the square cell pattern.

FIG. 5 is a cross sectional view illustrating an arrangement of a substantial part of a conventional trench MOSFET.

FIG. 6 is a diagram illustrating component resistances of ON resistance in the trench MOSFET.

FIG. 7(a) is a plane view illustrating one example of a layout pattern of a trench section, a source diffusion section, and a body diffusion section in a conventional trench MOSFET.

FIG. 7(b) is a plane view illustrating an example of a layout pattern of a trench section, a source diffusion section, and a body diffusion section in a conventional trench MOSFET.

FIG. 7(b) is a plane view illustrating an example of a layout pattern of a trench section, a source diffusion section, and a body diffusion section in a conventional trench MOSFET.

### BEST MODE FOR CARRYING OUT THE INVENTION

Under this heading, a novel trench MISFET (including MOSFET) and its manufacturing method will be described in details according to the present invention. The present embodiment will focus on the present invention being applied to a p-type trench MOSFET. Namely, in the p-type MOSFET in the following explanation, a first conductive type is p-type and a second conductive type is n-type. One with ordinary skill in the art would easily understand that the present invention is applicable not only to p-type trench MOSFETs, but also to n-type trench MOSFETs (where a first conductive type is n-type and a second conductive type is p-type).

In the trench MOSFET of the present invention, a layout pattern of body contacts and trench sections can be applied to many trench MOSFET variations. The following embodiment is one referential example.

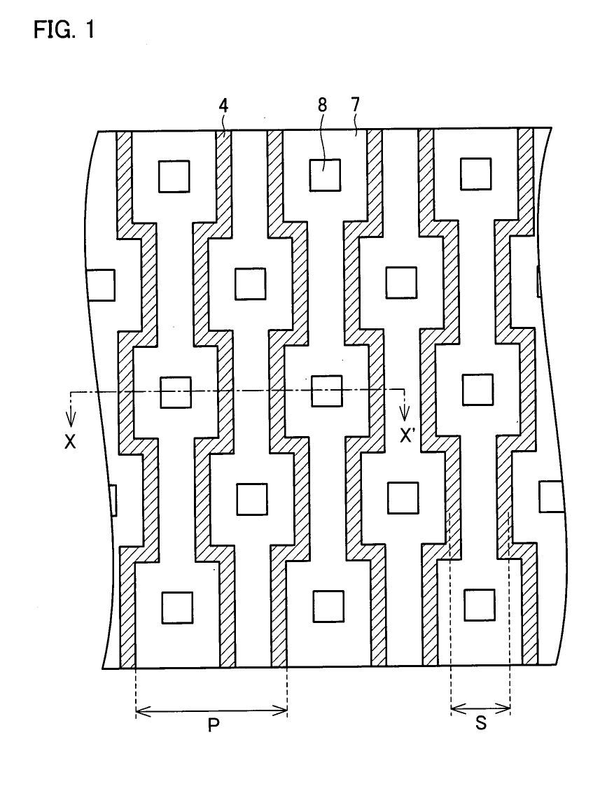

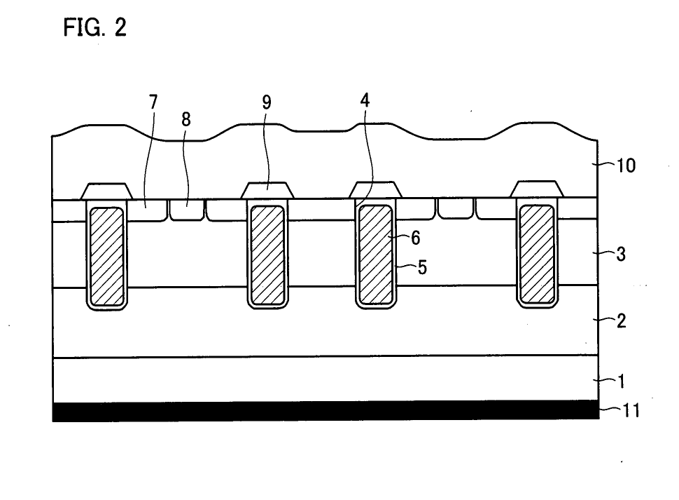

FIG. 1 illustrates a gate electrode structure and a pattern of contact sections of a source and a body (namely, body contacts) as a basic layout of the trench MOSFET of the present invention. FIG. 2 illustrates a cross section taken along X-X′ of the trench MOSFET as illustrated in FIG. 1.

First, a silicon substrate 1 is typically p-type doped to achieve a resistivity from 0.01 Ω.cm to 0.005 Ω.cm and has a thickness from 500 μm to 650 μm. After the trench MOSFET is fabricated, the substrate 1 is thinned down to approximately 100 μm to 150 μm by back lapping.

The epitaxial layer (Epi layer) 2 is formed by epitaxially growing a P layer on the P⁺ substrate 1, the P layer being less doped than the substrate 1. The thickness Xepi and resistance ρepi of the epitaxial layer 2 thus formed may be specified depending on the ultimate electrical characteristics the trench MOSFET is required to possess. In typical cases, the resistance of the epitaxial layer 2 should be lowered to reduce the ON resistance of the trench MOSFET. However, there is a tradeoff between the resistance of the epitaxial layer 2 and the breakdown voltage.

The body section 3 of the trench MOSFET of the present embodiment is of n-type. The body section 3 is formed by implanting phosphorous atoms so that the top surface of the silicon has a doping concentration from 5×10¹⁶ to 7×10¹⁷ (atoms/cm³). The n-type body section 3 is designed to realize a PN junction with the epitaxial layer 2 at a depth Xn from 2 μm to 5 μm. The values may vary depending on the electrical characteristics of the trench MOSFET. For example, in a case of the device operating at 40 V, the epitaxial layer 2 is typically designed to have an Xn range from 2.5 μm to 3 μm.

Trench sections 4 are formed in the substrate 1, the epitaxial layer 2, and the body section 3 by a regular photo etching technique. After the silicon trench etching, a gate dielectric film (oxide film) 5 is grown to the thickness appropriate for an ultimate electric characteristic of the device, on the inner wall of each of the trench sections 4. Generally, the thickness of the gate dielectric film 5 is from 10 nm to 150 nm.

In the trench MOSFET of the present embodiment, the depth of the trench section 4 is typically from approximately 1.5 μm to 5 μm. The depth of a channel section (channel body) is slightly shallower than the depth of the trench section 4. The width of the trench section 4 is typically from 0.51 μm to 3 μm. The bottom of the trench section 4 is positioned at substantially the same place as the interface between the epitaxial layer 2 and the substrate 1. The trench section 4 is partly surrounded by the epitaxial layer 2 that is a drift section.

A gate electrode material that is generally made of polysilicon fills up the trench section 4. Namely, the gate electrode section 6 is embedded in the trench section 4. The gate electrode section 6 is insulated from a source diffusion section 7 by the gate dielectric film 5. In fabrication of this device, POCl₃ is used as a doping source to dope the polysilicon with phosphorous. After the doping, the polysilicon is subjected to planarization to remove the polysilicon from the flat surface of the wafer. Accordingly, the polysilicon which will form the gate electrode section 6 is left only to fill up the trench section 4.

Source diffusion sections 7 and channel body diffusion sections 8 can be formed in the same layer on the body section 3 with a method involving publicly well-known photoresist masking and ion implantation. FIG. 1 illustrates one example of the layout of the source diffusion sections 7 and the body diffusion sections 8. Each of the p⁺ source diffusion sections 7 is formed by implanting a p-type dopant (¹¹B⁺ or BF₂⁺) to a concentration (dose) from approximately 1×10¹⁵ cm⁻² to 3×10¹⁵cm⁻² so that a PN junction is formed at a depth from 0.2 μm to 0.5 μm. Similarly, each of the body diffusion sections 8 is formed by implanting an n-type dopant (³¹P⁺ or ⁷⁵As⁺) to a concentration from approximately 1×10¹⁵ to 3×10¹⁵ so that the junction is formed at a depth from 0.2 μm to 0.5 μm. These steps may be replaced with a silicidation step (silicidation process) for the p-type source diffusion sections 7 and the n-type channel body diffusion sections 8.

Lastly, an interlayer insulator layer 9 for protection of the gate electrode section 6, contact holes, and an upper metal layer 10 are formed by a conventional, publicly known manufacturing method for typical IC devices. Furthermore, after the wafer is thinned down to a thickness from 100 μm to 150 μm by back lapping, a metallization stack is formed on the backside of the wafer (the substrate 1) and alloyed by a 10-minute treatment in a forming gas at 430° C. As a result, a lower metal layer 11 is formed.

One example of a trench MOSFET of the present embodiment is realized by providing the trench sections 4 in a meander type pattern as illustrated in FIG. 1. In the meander type pattern, each of the trench sections 4 is formed in a zigzag shape. Further, two adjacent trench sections 4 are provided to be axisymmetrical, having an axis of symmetry in a longitudinal direction (a vertical direction of FIG. 1) of the trench sections 4. Each of the source diffusion sections 7 partitioned by the trench sections 4 has a wide region and a narrow region alternately formed. The body diffusion sections 8 are provided in the wide regions of the source diffusion sections 7.

An effect of the layout above is shown by comparing each ratio Y of a MOSFET channel width Wu to a cell area Au. The ratio Y indicates an efficiency of the trench MOSFET layout and is illustrated by the following equation (2):

Y=Wu/Au (2)

In the layout as illustrated in FIG. 1, as explained above, each of the source diffusion sections 7 has the wide region and the narrow region alternately formed. The body diffusion sections 8 are provided in the wide regions of the source diffusion sections 7. Therefore, while the body diffusion sections 8 (body contacts) are kept in the layout, it is possible, as a whole, to prevent an increase in the width between the trench sections 4. In other words, the area Au per unit cell can be reduced.

Moreover, the trench sections 4 are formed in a zigzag shape. This increases a periphery length of each of the trench sections 4 in the plane as illustrated in FIG. 1, compared with a case where each trench section 4 is formed in a straight line. This, subsequently, increases the channel width Wu of the MOSFET.

In other words, in the trench MOSFET of the present embodiment, the layout of the trench sections 4 has the pattern layout as illustrated in FIG. 1. This leads to an effect such that, in the right side of the equation (2), the cell area Au being a denominator is reduced and the channel width Wu being a numerator is increased. This makes it possible to increase the layout efficiency of the trench MOSFET (reduce the ON resistance).

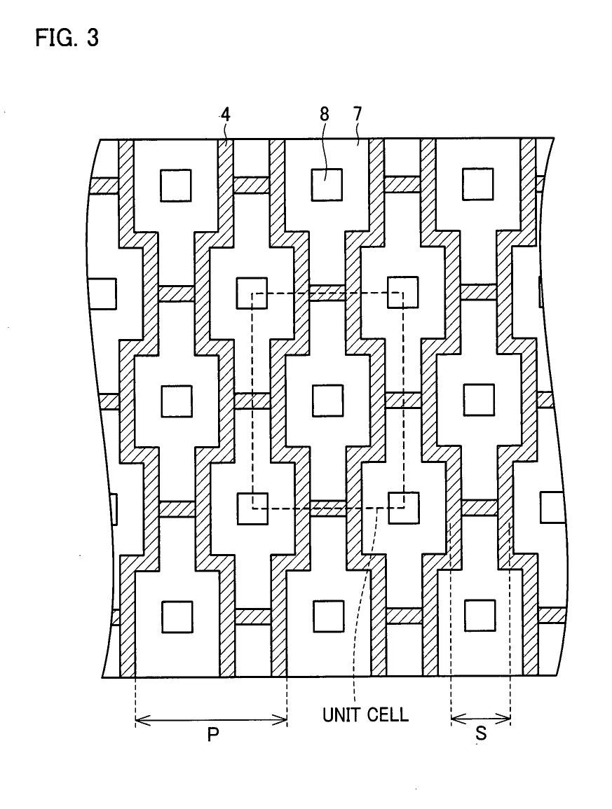

A modified example of the trench MOSFET of the present embodiment is realized by providing the trench sections 4 in a keyhole type pattern as illustrated in FIG. 3. Different from the meander type pattern, in the keyhole type pattern, adjacent trench sections 4 are formed so as to connect to each other in the narrow regions of the source diffusion sections 7. This causes the individual unit cell to be surrounded by the trench sections 4 in the keyhole type pattern.

In the layout as illustrated in FIG. 3, as explained above, each of the source diffusion sections 7 has a wide region and a narrow region alternately formed. The body diffusion sections 8 are provided in the wide regions of the source diffusion sections 7. Therefore, as with the meander type pattern, while the body diffusion sections 8 (body contacts) are kept in the layout, it is possible, as a whole, to prevent an increase in the width between the trench sections 4.

The individual unit cell becomes a polygon that is formed by a combination of the wide region and the narrow regions. Compared with a square cell or a hexagon cell, this increases a periphery length of each of the trench sections 4 in the plane as illustrated in FIG. 3. Consequently, the channel width Wu of the MOSFET can be increased.

Furthermore, as anticipated from the shape on the plane, compared with the meander type pattern as illustrated in FIG. 1, the keyhole type pattern as illustrated in FIG. 3 has a wider trench gate width. This further increases a channel area per unit area. In other words, the area efficiency becomes higher (ON resistance is lower) in the keyhole type pattern than in the meander type pattern.

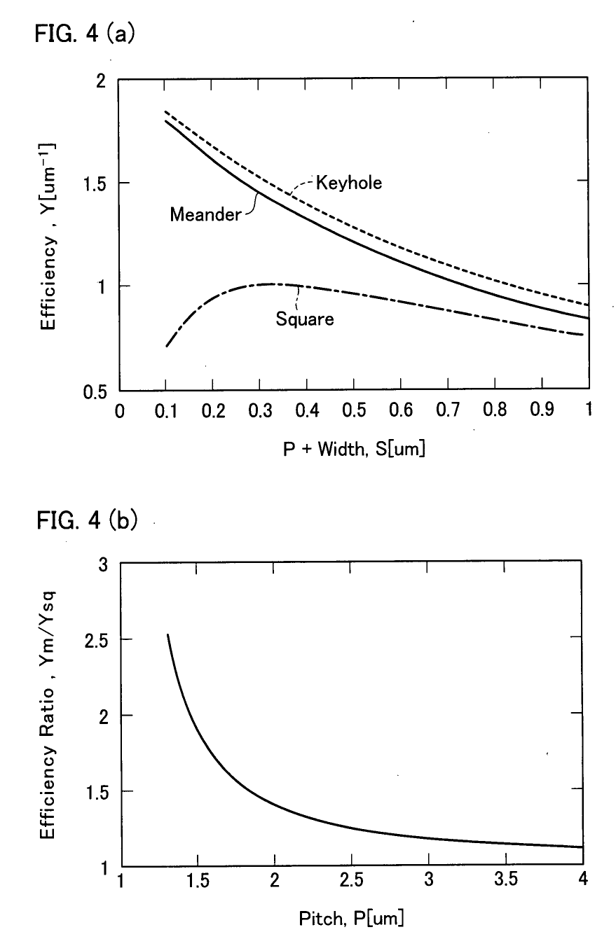

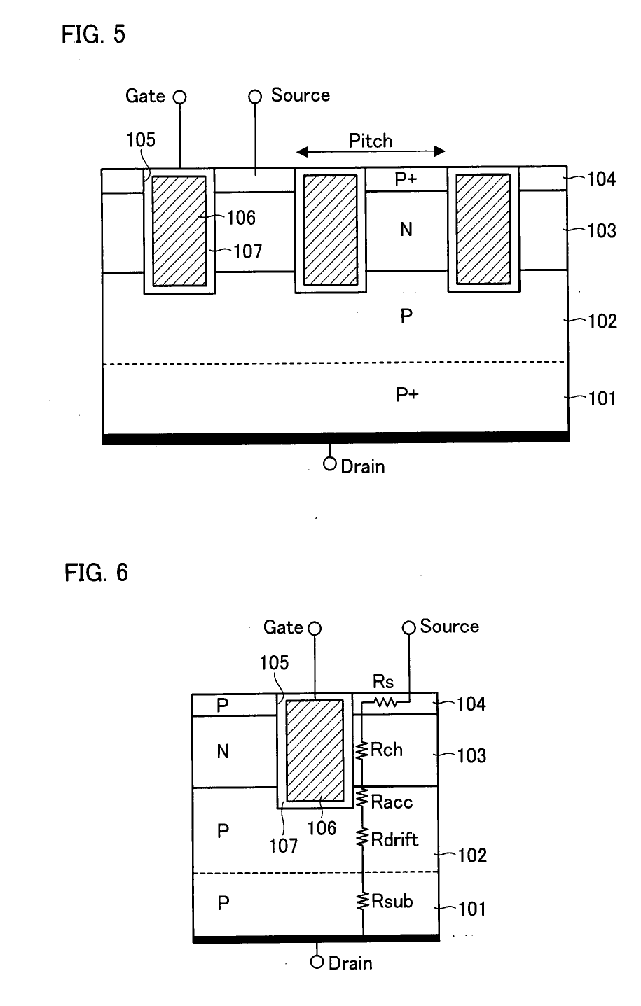

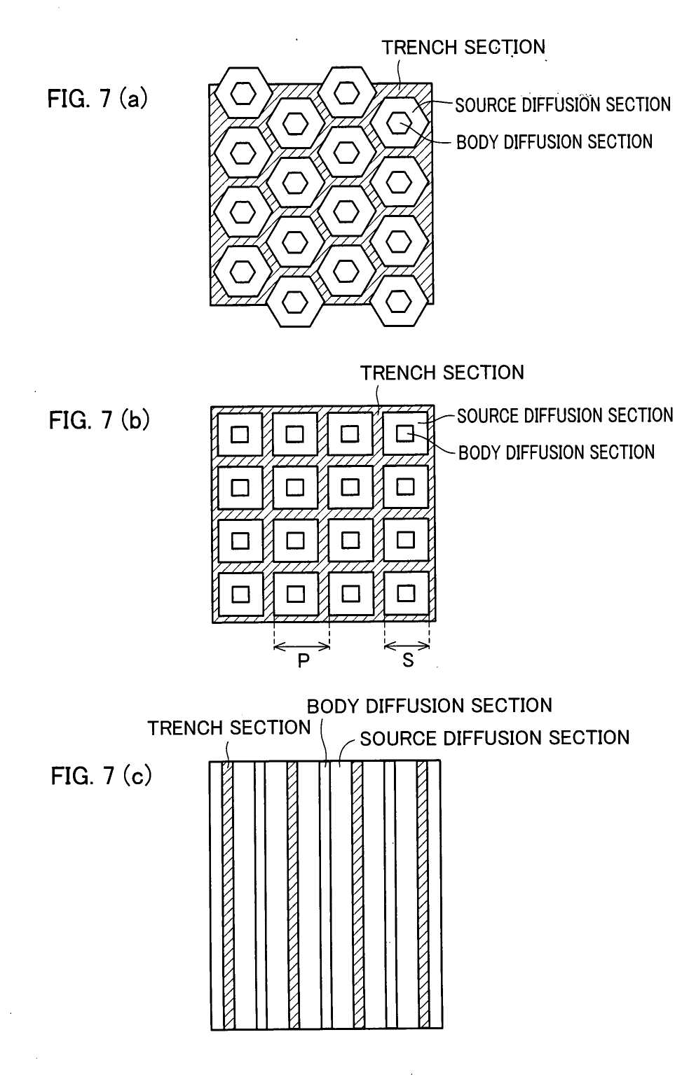

FIG. 4(a) shows a result of comparing effects of the square cell pattern as illustrated in FIG. 7(b), the meander cell pattern as illustrated in FIG. 1, and the keyhole cell pattern as illustrated in FIG. 3. In FIG. 4(a), a horizontal axis indicates a width S of the source diffusion sections 7 as a parameter indicating a cell size and a vertical axis indicates an efficiency Y calculated by the equation (2). A width of the source diffusion sections 7 in the meander cell pattern is shown by an average width in a horizontal direction of FIG. 1 and a width of the source diffusion sections 7 in the keyhole cell pattern is shown by an average width in a horizontal direction of FIG. 3. The width S of the source diffusion sections 7 is illustrated in each of the FIG. 7(b), FIG. 1, and FIG. 3.

FIG. 4(b) illustrates a ratio of the efficiency of the meander cell pattern to the efficiency of the square cell pattern. In FIG. 4(b), the horizontal axis indicates a cell pitch P. A size of the cell pitch P is illustrated in each of the FIG. 7(b), FIG. 1, and FIG. 3.

As shown in FIG. 4(a), in the meander cell pattern and the keyhole cell pattern, the smaller the width S of the source diffusion sections 7 becomes, the higher the efficiency Y becomes. This is because reduction in the width S of the source diffusion sections 7 leads to reduction of the area of the unit cell. On the other hand, in the square cell pattern, the efficiency Y is at a peak when the width S of the source diffusion sections 7 is approximately 0.3 μm. The further reduction of the width S of the source diffusion sections 7 does not increase the efficiency Y. This is because, in the square cell pattern, a reduction in the width S of the source diffusion sections 7 inevitably leads to a reduction in each region of the body contacts, i.e. each area of the body diffusion sections 8. This hampers the increase in the efficiency Y.

On the other hand, in the meander cell pattern and the keyhole cell pattern of the present embodiment, an area of the body diffusion sections 8 can be maintained even if the width S of the source diffusion sections 7 is reduced. Accordingly, the efficiency Y can be increased when the width S of the source diffusion sections 7 is reduced. Therefore, as shown in FIG. 4(b), the smaller the width S of the source diffusion sections 7 becomes, more drastically the efficiency ratio of the efficiency of the meander cell pattern to the efficiency of the square cell pattern increases. Compared with the conventional square type pattern, at least approximately 40 percent increase in the efficiency is anticipated from a meander type pattern at a cell pitch P of 2 μm. Moreover, it is clear that the pattern proposed in the present embodiment is more advantageous in that the proposed pattern reduces a unit cell size of a transistor.

A trench MISFET includes trench sections, on a semiconductor substrate, in which a gate electrode is embedded, the substrate including: a heavily doped drain section of a first conductive type; a lightly doped drain section of the first conductive type; a channel body section of a second conductive type; and a source section of the first conductive type, the sections being formed in this order adjacently, source diffusion sections and body diffusion sections being formed in the source section, the trench sections causing regions where the source diffusion sections and the body diffusion sections are formed to be partitioned by alternately forming a wide region and a narrow region in each of the regions where the source diffusion sections and the body diffusion sections are formed, and each of the body diffusion sections being provided in wide regions in each of the regions partitioned by the trench sections.

The arrangement includes body contacts (contact sections each being between the source and the body) for providing electric potential to the channel body section by formation of the source diffusion sections and the body diffusion sections in the source section. The formation of such body contacts, namely, provision of the body diffusion sections is necessary for causing a MISFET to perform a correct device operation. However, the formation of each of the body contacts consumed a large area in a cell area and lead to an increase in the cell area. This deteriorated the efficiency of the MISFET.

On the other hand, according to the arrangement mentioned above, a wide region and a narrow region are alternately formed in the regions, including the source diffusion sections and the body diffusion sections, which regions are partitioned by the trench sections. Each of the body diffusion sections is provided in the wide region. This makes it possible, as a whole, to prevent each width between the trench sections from increasing while the body diffusion sections (body contacts) are kept in the arrangement. In other words, the area per unit cell can be reduced.

Moreover, for alternate formation of the wide region and the narrow region in the regions including the source diffusion sections and the body diffusion sections, the trench sections are formed to have, for example, a zigzag-shaped part. This increases the length of the periphery of each of the trench sections in a plane, compared with a case where each of the trench sections is formed in a straight line. This leads to an increase in the channel width of the MOSFET.

Namely, in the trench MOSFET, the pattern layout of the trench sections, the source diffusion sections, and the body diffusion sections as mentioned above leads to an effect such that a cell area is reduced and a channel width is increased. Accordingly, the efficiency of the trench MOSFET can be increased (ON resistance can be reduced).

In the trench MISFET of the present invention: the trench sections may cause each of the regions where the source diffusion sections and the body diffusion sections are formed to be partitioned into individual unit cells.

According to the arrangement, the trench gate width increases further. Subsequently, a channel area per unit area can be increased.

In the trench MISFET of the present invention: it is preferable that the semiconductor substrate is made of silicon.

1. A trench MISFET comprising trench sections, on a semiconductor substrate, in which a gate electrode is embedded, the substrate including: a heavily doped drain section of a first conductive type; a lightly doped drain section of the first conductive type; a channel body section of a second conductive type; and a source section of the first conductive type, the sections being formed in this order adjacently,
source diffusion sections and body diffusion sections being formed in the source section,
the trench sections causing regions where the source diffusion sections and the body diffusion sections are formed to be partitioned by alternately forming a wide region and a narrow region in each of the regions where the source diffusion sections and the body diffusion sections are formed, and
each of the body diffusion sections being provided in wide regions in each of the regions partitioned by the trench sections.

2. The trench MISFET as set forth in claim 1, wherein:
the trench sections cause each of the regions where the source diffusion sections and the body diffusion sections are formed to be partitioned into individual unit cells.

3. The trench MISFET as set forth in claim 1, wherein:
the semiconductor substrate is made of silicon.
